(19) United States
(12) Patent Application Publication
(10) Pub. No.: US 2018/0358182 A1
(43) Pub. Date: Dec. 13, 2018

(54) METHOD FOR PRODUCING A LAYER WITH PEROVSKITE MATERIAL

(71) Applicants: Maximilian Fleischer, Höhenkirchen (DE); Ralf Moos, Bayreuth (DE); Tanaji Gujar, Bayreuth (DE); Dominik Hanft, Bayreuth (DE); Fabian Panzer, Bayreuth (DE); Mukundan Thelakkat, Bayreuth (DE)

(72) Inventors: Maximilian Fleischer, Höhenkirchen (DE); Ralf Moos, Bayreuth (DE); Tanaji Gujar, Bayreuth (DE); Dominik Hanft, Bayreuth (DE); Fabian Panzer, Bayreuth (DE); Mukundan Thelakkat, Bayreuth (DE)

(21) Appl. No.: 16/104,732

(22) Filed: Aug. 17, 2018

Related U.S. Application Data
(63) Continuation of application No. PCT/EP2017/053636, filed on Feb. 17, 2017.

(30) Foreign Application Priority Data
Feb. 19, 2016 (DE) 102016202607.0

(51) Int. Cl. H01G 9/00; C23C 24/04; C23C 28/04; H01L 51/00; H01L 51/42; H01L 51/50; H01L 27/30; H01G 9/20

(52) U.S. Cl. CPC H01G 9/0036; C23C 24/04; C23C 28/04; H01L 51/0008; H01L 51/0029; H01L 2251/558; H01L 51/5032; H01L 27/308; H01G 9/2009; H01L 51/0077; H01L 51/4253

(57) ABSTRACT

A method is provided for producing an electro-optical and/or optoelectronic layer. In the method, the layer is formed with perovskite material of the composition ABX₃ by cold gas spraying at least a starting material having the perovskite material. X is also formed with at least one halogen or a mixture of multiple halogens. In the method for producing an electro-optical or optoelectronic device with at least one electro-optical or optoelectronic layer, the at least one electro-optical or optoelectronic layer is formed with a perovskite material by the method. The device is, in particular, an electro-optical or optoelectronic device, such as an energy converter, a solar cell, a light diode, or an X-ray detector. The device has an electro-optical layer of this type.

### CROSS REFERENCE TO RELATED APPLICATIONS

The present patent document is a continuation of PCT Application Serial Number PCT/EP2017/053636, filed Feb. 17, 2017 designating the U.S., which is hereby incorporated by reference in its entirety. This patent document also claims the benefit of DE 102016202607.0, filed on Feb. 19, 2016, which is also hereby incorporated by reference in its entirety.

### FIELD

Embodiments relate to a method of manufacturing a layer including perovskitic material, to a method of producing an electrooptical and/or optoelectronic device.

### BACKGROUND

For some years, perovskitic materials, for example CH₃NH₃PbI₃, have been gaining increasing significance owing to their optoelectronic properties. Perovskitic materials have gained attention as high-efficiency, electrooptical or optoelectronic semiconductor materials since perovskites permit efficient conversion of electrical energy to electromagnetic radiation energy and of electromagnetic radiation energy to electrical energy. Use of perovskitic material in solar cells leads to an increase in efficiency to more than twice the previous standard.

In high-efficiency semiconductor components, layers of electrooptical semiconductor material are regularly required. Numerous methods are known for layer production of perovskitic material.

The methods include, for example, the OSPD (“one-step precursor deposition”) method, two-source coevaporation, the SDM (“sequential deposition method”), the VASP (“vapor-assisted solution process”) method, the interdiffusion method and the method of spray coating from solution.

In spite of the promising properties of perovskitic material mentioned, there has to date been no large-scale use in optoelectronic components. For example, manufacture high-efficiency components including perovskitic material have been possible only under laboratory conditions and under suitable ambient atmospheres. Perovskitic material does not have sufficient long-term stability at present under the influence of ambient air: for example, water molecules destroy the crystal lattice structure of the perovskitic material.

Moreover, the production of relatively large areas or the production of layers of relatively large thickness remains complex and costly.

### BRIEF DESCRIPTION AND SUMMARY

The scope of the present invention is defined solely by the appended claims and is not affected to any degree by the statements within this summary. The present embodiments may obviate one or more of the drawbacks or limitations in the related art.

Embodiments provide a method of manufacturing a layer including perovskitic material that is simple and inexpensive and provides a material having improved long-term stability. Embodiments provide a method of producing an electrooptical and/or optoelectronic device and a device, for example, an electrooptical or optoelectronic device, including a layer including perovskitic material that may be implemented inexpensively and provide long-term stability.

In an embodiment of a method for manufacturing an electrooptical and/or optoelectronic layer, the layer including perovskitic material of the composition ABX₃ is formed by cold gas spraying of at least one starting material including the perovskitic material. X is formed by at least one halogen or a mixture of two or more halogens. The term “perovskitic material” in the context of this application is understood to refer to a material including a perovskitic crystal structure of the ABX₃ form. The A position is occupied by a cation or a mixture of different cations, the B position by a metallic or semi-metallic cation or a mixture of different cations, and the X position, as already described above, by a halogen or a mixture of different halogens. The composition also includes materials includes a stoichiometry that differs slightly from A:B:X=1:1:3, i.e. by at most 0.05 from the proportion specified in each case.

In an embodiment of a method, the starting material including the perovskitic material is in powder form that is converted to a layer, appropriately at room temperature. The perovskitic material forms an aerosol with a stream of cold gas. The gas temperature may be at most 200 degrees Celsius, at most 70 degrees Celsius, or at most 40 degrees Celsius. The aerosol forms a stream of the starting material including the perovskitic material onto a substrate, with aggregation of the material to form a continuous layer.

The aerosol is driven through a nozzle owing to a pressure differential and accelerated in the process.

The aerosol may be accelerated against a low pressure of at most one hundred, for example, of at most ten, mbar that may be referred to as aerosol deposition method (ADM) or—synonymously—as aerosol-based cold deposition.

The powder during the coating undergoes barely any change in its chemical composition, if any. By contrast, for methods known to date that the perovskitic material undergoes chemical change during the coating or is only formed in the coating operation. According to embodiments, the perovskitic material may therefore advantageously first be synthesized and subsequently converted to a layer virtually without any change in the chemical structure.

Embodiments provide for manufacture of a compact, e.g. a dense and nonporous, layer including perovskitic material. The contact area between perovskitic material and ambient atmosphere is kept extremely small. Only a relatively small proportion of the perovskitic material is exposed to water molecules from the ambient atmosphere, and so the perovskitic lattice structure is substantially conserved. Any significant deterioration in relevant material properties for use as active semiconductor material is consequently effectively prevented. For a layer including perovskitic material that is manufactured in accordance with an embodiment, any deterioration in charge carrier mobility, that otherwise is taken into account, and accordingly any decrease in the diffusion lengths, resulting in a blue shift of the absorption edge, known as the so-called “yellow changeover”, occur in a greatly retarded manner, if at all.

High-efficiency devices including perovskitic material that are suitable for practical use may be manufactured. The long-term stability of layers including perovskitic material thus reaches marketable values. Consequently, even in the case of devices including layers including perovskitic material, the lifetime of the devices is not necessarily limited by that of the perovskitic material, e.g. the long-term stability of the layers and devices is distinctly improved.

Moreover, the crystal lattice structure of the perovskitic material is conserved. Specifically, in the case of films, in the conventional production of layers including perovskitic material, residues of the starting material that remain are found to be disadvantageous. Residues of lead iodide have a distinct effect on the long-term stability of layers including perovskitic material. For example, in the case of the conventional OSPD method, such residues are a problem. Embodiments provide that any such unwanted effect on the manufactured layer is already ruled out owing. No other changes in the crystal lattice structure of the perovskitic material occur either.

In addition, the method may be conducted easily and inexpensively. The implementation of high layer thicknesses of at least one micrometer or more is readily achievable by the method.

Further advantageously, very small layer thicknesses of less than one micrometer and less than 300 nanometers are also easily possible through appropriate choice of the method parameters.

Layer thicknesses in the sub-micrometer range down to the high micrometer range are achievable and layers thus manufactured are suitable for a wide variety of different applications. Manufacturing two-dimensional areas of layers including perovskitic material of any extent is also possible.

Cold gas spraying is affected by aerosol-based cold deposition. Embodiments may be conducted at a temperature of at most 200 degrees Celsius, at most 70 degrees Celsius, or at most 40 degrees Celsius.

The retention of the perovskite lattice structure of the perovskitic material is assured in a simple manner since the comparatively low breakdown temperature is not attained in this way.

Consequently, the method opens up inexpensive manufacture also of thick and/or large-area layers by comparison with known methods.

Since, by comparison with conventional methods, for example as specified above, the material synthesis (for example from solution) does not coincide directly with the layer formation, and the two steps may instead be conducted separately from one another, the method provides a higher degree of process control and optimization of material and layer formation. Moreover, a high deposition rate enables coating of large areas within a short time and thus in an economically viable manner.

For the aerosol-based cold deposition, a plant as described in U.S. Pat. No. 7,553,376 B2 may be used. The disclosure content of the published specification cited is explicitly incorporated by reference in so far as it relates to the plant or the execution of the method.

In an embodiment, the cold gas spraying is conducted in an operating atmosphere including at most 30 percent relative humidity, at most 20 percent relative humidity, or at most 10 percent relative humidity. In the method, the cold gas spraying is conducted in an operating atmosphere (also referred to as chamber pressure in the literature) with a pressure of at most 100 bar or at most 10 mbar.

The generation of extraneous phases that may act as degradation seeds is avoided during the method. The retention of the perovskite lattice structure of the starting material present in the starting material that is envisaged is readily possible. Any chemical change in the perovskitic material is effectively avoided.

In an embodiment, the cold gas spraying is conducted in inert atmosphere.

The generation of extraneous phases that may act as degradation seeds is effectively avoided.

In an embodiment, the layer is formed with a layer thickness, at least in regions, of at least one, e.g. at least three, and appropriately at least ten micrometers. The layer is formed with a layer thickness, at least in regions, of at least 30, e.g. at least 100, micrometers.

In an embodiment, the layer is formed with a layer thickness, at least in regions, of at most 1 μm, at most 500 nm or at most 200 nm.

The layers of perovskitic material reach such thicknesses as required in optoelectronic components such as energy transducers and radiation detectors, for example, x-ray detectors.

In an embodiment, the layer is formed with a mixture including the perovskitic material and at least one further material that is especially non-perovskitic and may form islands in the perovskitic material.

In an embodiment, the layer is formed as at least one sublayer in a succession of this at least one sublayer and at least one further sublayer. The at least one further sublayer is formed with at least one further, especially non-perovskitic, material.

The at least one further material may be an electron-conducting and/or electron-collecting material, e.g. TiO₂, and/or a hole-conducting and/or hole-collecting material, e.g. spiro-MeOTAD, and/or an electrically insulating material and/or an injection material, e.g. PEDOT:PSS or F8, and/or an inert material and/or an optically transparent material, especially glass and/or quartz and/or FTO (“fluorine-doped tin oxide”) glass.

The contact zone between the individual functional materials or functional layers is optimized, that according to the further material, provides better charge carrier extraction in collection layers and/or optimizes the light-emitting properties of the layer and/or prevents possible ion exchange in the case of processing of different variants of perovskitic material.

The gas component utilized in the aerosol-based cold deposition may be oxygen and/or nitrogen and/or an inert gas, e.g. argon and/or helium, and/or hydrogen and/or mixtures with hydrogen.

In production of an electrooptical and/or optoelectronic device having at least one electrooptical and/or optoelectronic layer, the at least one electrooptical and/or optoelectronic layer including a perovskitic material is formed by a method for manufacture of a layer including perovskitic material as described above.

In electrooptical and/or optoelectronic devices, the manufacture of an electrooptical and/or optoelectronic perovskitic layer of maximum density is crucial. By the method, as described above, the electrooptical and/or optoelectronic layer may be manufactured in dense form and with high layer thickness. The device including such a layer consequently includes high electrooptical and/or optoelectronic efficiency and at the same time a long lifetime.

The device may be an energy transducer or a radiation detector, e.g. an x-ray detector, and/or the electrooptical and/or optoelectronic layer is a sensor layer.

For devices in the form of energy transducers and radiation detectors, the manufacture of the electrooptical and/or optoelectronic perovskitic layer with a high layer thickness and low porosity is crucial for its efficiency and lifetime. The prerequisites that are essential for the practical utility of the device may readily be achieved.

In an embodiment, at least one further sensor layer is manufactured in a direction oblique, e.g. at right angles, to a direction of growth of the at least one sensor layer.

“Direction of growth” refers to the direction in which the layer adds on, e.g. appropriately the normal to a surface of the substrate on which the layer adds on and/or the normal to the two-dimensional extents of the layer.

In the case of radiation detectors, multiple sensor layers may be implemented in the manner of detector pixels, such that spatially resolved detection of electromagnetic radiation is possible if appropriate.

In an embodiment, a device including at least one layer including perovskitic material is formed.

The device may be an energy transducer configured for conversion of electromagnetic energy to electrical energy or of electrical energy to electromagnetic energy.

The device may be a solar cell or a light-emitting diode.

The device may be an x-ray detector.

### BRIEF DESCRIPTION OF THE FIGURES

FIG. 1 depicts a plant for cold gas spraying for manufacture of a layer including a perovskitic material in the form of a schematic diagram according to an embodiment.

FIG. 2 depicts an example manufactured layer including perovskitic material in a top view.

FIG. 3 depicts an example manufactured layer in schematic form in longitudinal section.

FIG. 4 depicts a solar cell including an example of a layer sequence including an example manufactured optoelectronic sensor layer in schematic form in longitudinal section.

FIG. 5 depicts a light-emitting diode of a layer sequence including an example manufactured optoelectronic sensor layer in schematic form in longitudinal section.

FIG. 6 depicts an x-ray detector including a manufactured example optoelectronic sensor layer in schematic form in top view.

FIG. 7 depicts an x-ray detector including an example manufactured optoelectronic sensor layer in schematic form in top view.

FIG. 8 depicts the x-ray detector of FIG. 7 in schematic form in top view.

### DETAILED DESCRIPTION

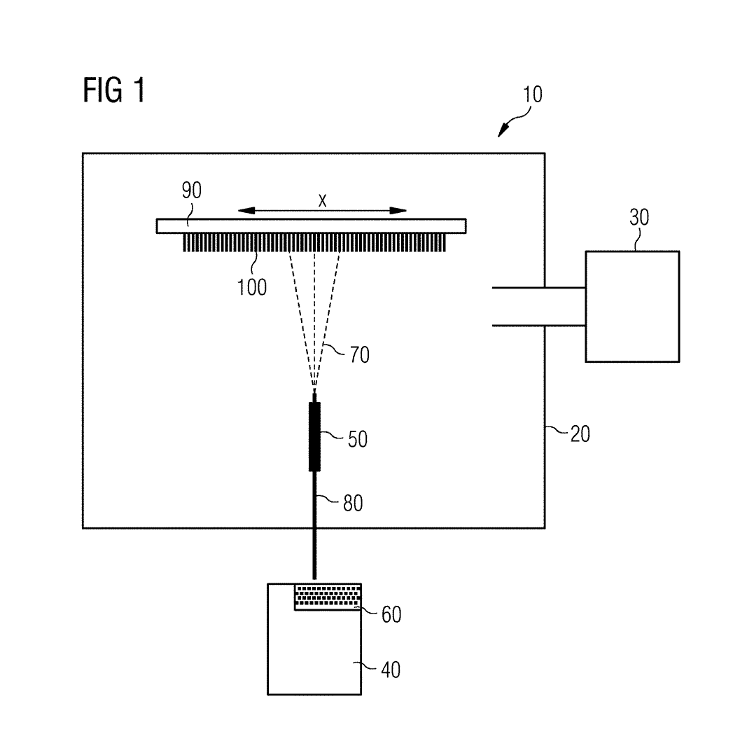

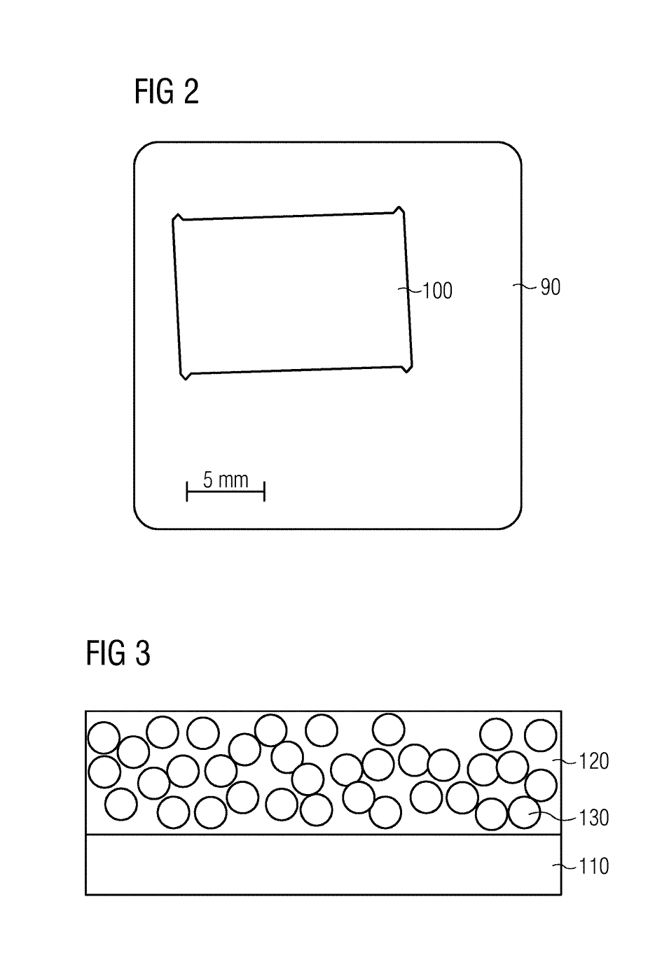

The plant 10 depicted in FIG. 1 is a cold gas spraying plant and, in the working example shown, is a plant 10 for aerosol-based cold deposition of powders. The plant 10 includes a vacuum chamber 20, a vacuum pump 30, an aerosol source 40 and a nozzle 50. Details of the construction of the plant 10 may be found, for example, in U.S. Pat. No. 7,553,376 B2, that may be applied without further adjustments to the present plant 10.

A method of an embodiment is conducted by the plant 10 as follows: the vacuum pump 30 pumps the vacuum chamber 20 to a vacuum, for example, to a reduced pressure of a few millibars, e.g. five millibars. The aerosol source 40 is outside the vacuum chamber 20 and mixes a gas, for example oxygen and/or nitrogen, with particles 60 of perovskitic material and provides an aerosol 70. The perovskitic material is provided beforehand by known chemical methods.

The aerosol source 40 is operated, for example, at standard pressure, e.g. atmospheric pressure. As a consequence of the pressure difference between aerosol source 40 and vacuum chamber 20, the particles 60 are transported from the aerosol source 40 into the vacuum chamber 20 via a connecting conduit 80 that connects the aerosol source 40 and the vacuum chamber 20. The connecting conduit 80 extends into the vacuum chamber 20 and, at an end within the vacuum chamber 20, opens into a nozzle 50 that further accelerates the aerosol stream and consequently the particles 60. In the vacuum chamber 20, the particles 60 meet a substrate 90 moving in x direction, where the particles 60 form a dense film 100.

The particles 60 in the aerosol source 40 are in the form of pulverulent perovskitic material prior to mixing with the gas component of the aerosol 40. The particles 60 form a likewise perovskitic film 100 on the substrate 90, with the perovskitic material remaining unchanged in its chemical structure throughout the method.

In an embodiment a structure control unit is provided, that monitors the crystal lattice structure of the film 100 by x-ray diffractometry. Measurements show that the perovskitic crystal lattice structure of the pulverulent starting material on application to the substrate 90 is regularly fully conserved. Secondary phases do not occur in the film 100.

In an embodiment, the perovskitic material is an organometallic halogen, CH₃NH₃PbI₃, the substrate 90 in the present case, a glass substrate. The perovskitic material may, in further working examples that are not presented separately, be a different perovskitic material including optoelectronic properties. Moreover, in further working examples that are not presented separately, other substrates may be used, for example glasses or substrates that have already been provided with other layers.

The perovskitic material CH₃NH₃PbI₃ used in the working example presented includes optoelectronic properties that identify the material as suitable as an energy transducer for conversion of electrical energy to electromagnetic radiation energy and vice versa. For example, the absorption spectrum of this perovskitic material includes an absorption edge in the wavelength range between 750 nanometers and 800 nanometers and an absorption across the entire visible wavelength range (350 nanometers to 800 nanometers). At an excitation wavelength of 405 nanometers for this perovskitic material, the emission spectrum may show a main maximum at 780 nanometers in the immediate proximity of the absorption edge. The absorption and emission characteristics mentioned are typical of other perovskitic materials too.

An embodiment of the aerosol-based cold deposition results in a crystalline structure including low porosity, e.g. including high density that corresponds to the theoretical density.

In an embodiment, extended layers and layers of virtually any thickness may be produced. For example, the layer 100 is manufactured in several hundreds of micrometers. The layer may, in further working examples that are not presented separately, be thinner by a factor of 10, for example. In addition, the method as presented hereinafter offers the possibility of combining multiple materials.

For example, in further working examples different pulverulent starting materials may be mixed before or during the process of aerosol-based cold deposition. For example, in a working example, different variants of perovskitic materials (e.g. CH₃NH₃PbI₃ and CH₃NH₃PbBr₃) are used.

In an embodiment, as depicted in FIG. 3, a mixture of one or more perovskitic layers 120 with one or more different other materials 130 (e.g. TiO₂ as electron conductor, hole conductors or electrically isolating materials) is deposited on a carrier substrate 110. The further non-perovskitic materials 130 form islands within the perovskitic layer 120, that are fully surrounded by the perovskitic material.

Using different starting materials, for example, the contact zone between the respective functional materials or functional layers is optimized, for example in order to provide better charge carrier extraction in collecting layers, in order to optimize the light-emitting properties of the functional material, or in order to prevent possible ion exchange in the processing of different variants of perovskitic materials.

In an embodiment, an LED includes a layer manufactured for conversion of electrical energy to optical energy. TiO₂ is the further material 130 in the manner of a “mesoporous perovskite solar cell”.

In further embodiments, such a mixture of layers is implemented by a sequence of layers of different materials.

For example, different materials may be deposited in succession: for example, perovskitic materials of different compositions are deposited and/or perovskitic materials are deposited successively with a different material, for example hole conductor, electron conductor, injection layers, inert material, optically transparent material, structure material etc., or mixtures of starting materials as described above.

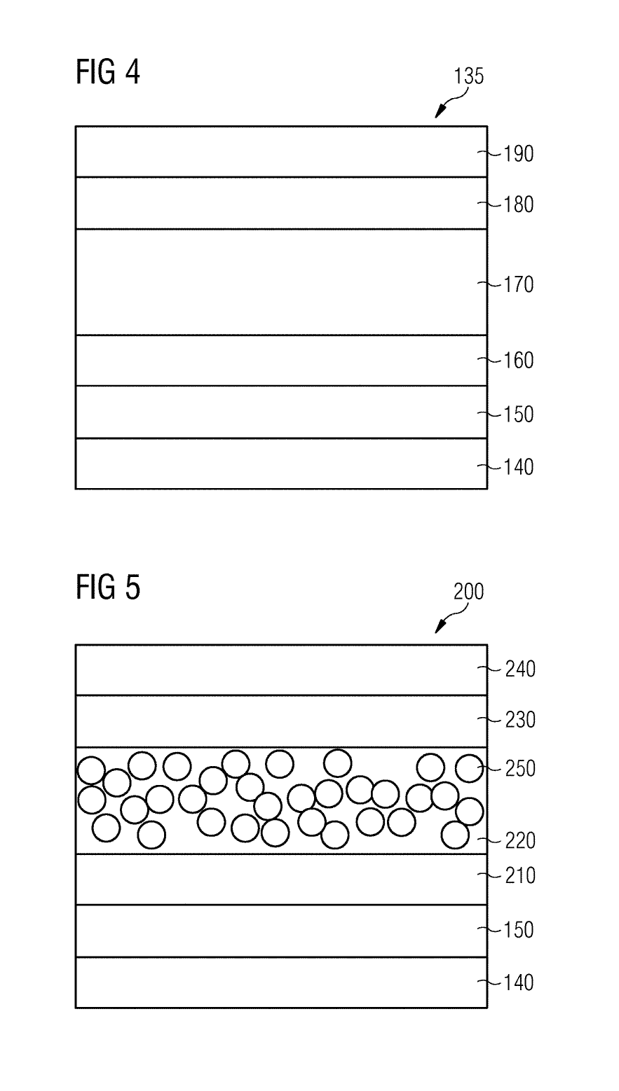

FIG. 4 depicts a schematic diagram of such a sequence of layers using the example of a solar cell 135.

The solar cell 135 forms a device with a layer including perovskitic material in the manner of an energy transducer and includes a carrier substrate 140 (glass in the present case, for example), and each of the following deposited successively layer by layer: a transparent electrode 150 formed with FTO (“fluorine-doped tin oxide”) glass in the example shown, an electron collecting layer 160 (TiO₂ in the present case, for example), an electrooptical and optoelectronic, perovskitic layer 170 (for example CH₃NH₃PbI₃), a hole collecting layer 180 (for example spiro-MeOTAD), and an electrode 190 (for example gold. At least the electrooptical and optoelectronic layer formed with perovskitic material and, in other embodiments, one or more of the other layers have been produced by aerosol-based cold deposition. The electrooptical and optoelectronic perovskitic layer 170 may additionally, in an embodiment not presented separately, as well as perovskitic material, also additionally include other materials as elucidated above with reference to FIG. 3.

The mode of function of the solar cell 135 with the sequence of layers shown in FIG. 4 is as follows: electromagnetic radiation from beneath is incident vertically on the solar cell 135. The radiation passes through the transparent electrode 150 into the electrooptical and optoelectronic layer 170 formed with perovskitic material. The radiation is absorbed which entails the generation of charge carriers. The charge carriers are extracted by the electron and hole collecting layers 160 and 180, and flow away via the electrodes 150 and 190.

FIG. 5 depicts an embodiment of an energy transducer, for example, a light-emitting diode 200 including a sequence of multiple layers. The sequence includes (from the bottom upward in FIG. 5) a carrier substrate 140 (e.g. glass), a transparent electrode 150 (e.g. FTO), a transparent injection layer for holes 210 (e.g. PEDOT:PSS), an electrooptical and optoelectronic layer 220 formed with perovskitic material (e.g. CH₃NH₃PbI₃), an injection layer for charge carriers 230 (e.g. F8), and a metal electrode 240 (e.g. MoO₃/Ag). At least the electrooptical and optoelectronic layer 220 formed with perovskitic material are produced by aerosol-based cold deposition and, as well as the perovskitic material, also contain other materials 250 as elucidated above with reference to FIG. 3.

The mode of function of the light-emitting diode 200 is as follows: the application of an external voltage to the electrodes 150 and 240 causes injection of holes and electrons from the respective injection layers 210 and 230 into the electrooptical and optoelectronic layer 220 formed with perovskitic material, where light formed as a result of the recombination thereof can leave the light-emitting diode 200 through the transparent layers of carrier substrate 140, electrode 150, and injection layer 210. By production of layers from mixtures of one or more perovskitic materials and one or more suitable other materials by aerosol-based cold deposition, the properties of the electrooptical and optoelectronic layer 220 formed with perovskitic material are influenced such that, for example, an increase in the charge carrier recombination rate and hence modification/optimization of the luminous efficiency of the light-emitting diode 200 are achieved.

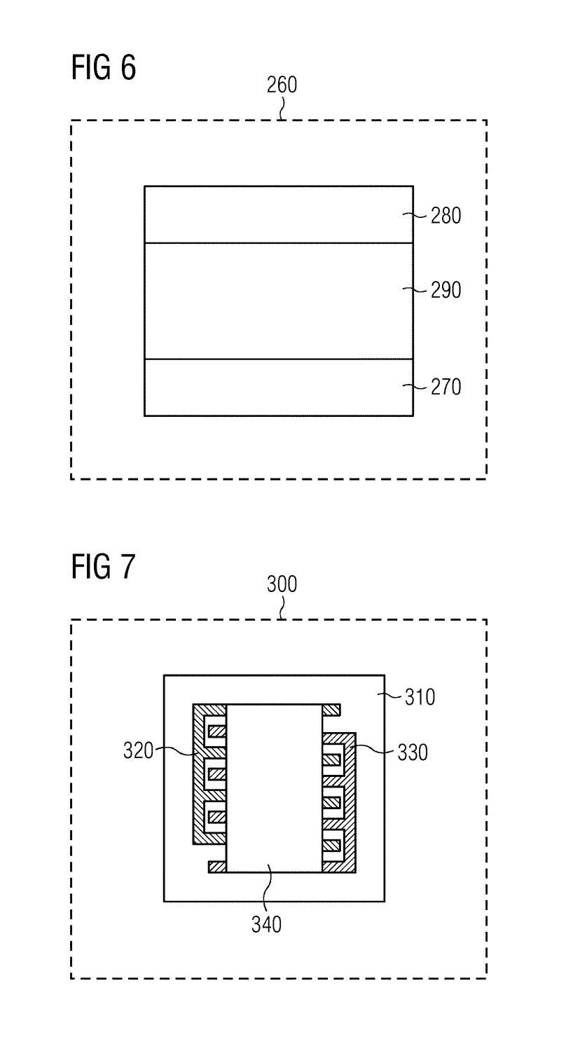

Further embodiments of a device including a layer including perovskitic material are depicted in FIGS. 6 to 8. The device depicted is an x-ray detector 260 configured for detection of electromagnetic radiation in the x-ray to UV range.

For this purpose, the x-ray detector 260 also includes a sequence of layers:

Similarly to the preceding embodiments, a first electrode 270 and a second electrode 280 surround an electrooptical and optoelectronic layer 290 formed with perovskitic material. The arrangement is manufactured by depositing the electrooptical and optoelectronic layer 290 formed with perovskitic material onto the first electrode 270 by aerosol-based cold deposition of perovskitic material. Subsequently, the further electrode 280 is applied to the layer 290.

The function of the x-ray detector is as follows: electromagnetic radiation in the x-ray to UV range, in the representation according to FIG. 6 in a horizontal direction of spread, is incident on the x-ray detector 260. The radiation is absorbed by the electrooptical and optoelectronic layer 290 formed with perovskitic material, and charge carriers are generated within this layer 290. In the case of layer thicknesses that exceed the intrinsic charge carrier diffusion length and in the case of which, therefore, there is no efficient charge carrier extraction at the electrodes 270, 280, there is a suitable external voltage on the electrodes 270, 280, for example, such that efficient charge separation is assured. A feature for efficient charge separation is high compactness, e.g. low porosity, of the electrooptical and optoelectronic layer 290 formed with perovskitic material, that is provided by the aerosol-based cold deposition. By measuring the photocurrent that is dependent on the incident electromagnetic radiation, and that flows away via the electrodes 270 and 280, the detection of electromagnetic radiation is possible with the aid of the x-ray detector 260.

Alternatively, the electrodes 270, 280 may be applied laterally to a substrate material and, in a subsequent step, covered with the electrooptical and optoelectronic layer of perovskitic material. Such a possible embodiment of an x-ray detector 300 is depicted in FIG. 7. The perovskitic material 340 is deposited with the aid of aerosol-based cold deposition onto an electrode structure present on a carrier substrate 310 (e.g. a finger electrode structure with the electrodes 320 and 330). Using the aerosol-based cold deposition, a suitable layer thickness depending on the wavelength/photon energy of the radiation to be detected is implemented.

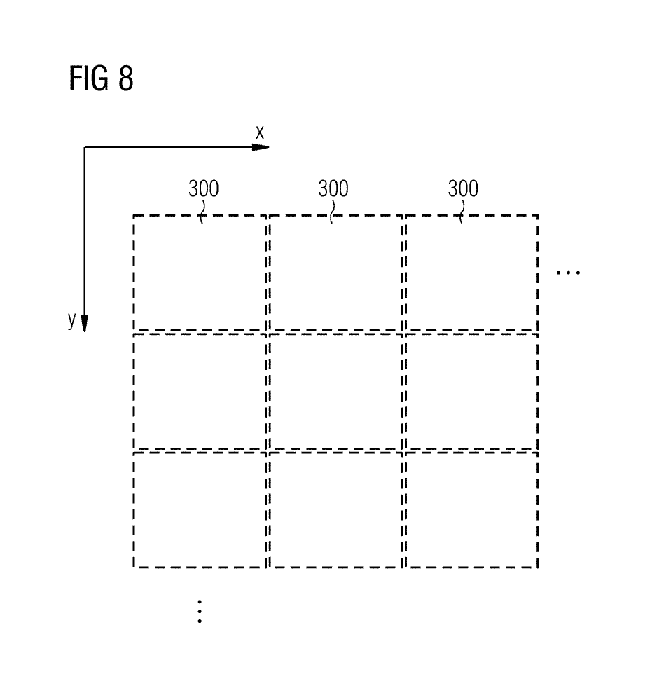

With the aid of the aerosol-based cold deposition, large-area coatings provide production of arrangements that provide spatially resolved detection of radiation. For such a detection of the photocurrent, in the working example according to FIG. 7, multiple x-ray detectors 300 are arranged alongside one another, e.g. offset in the two-dimensional extents of the electrooptical and optoelectronic layer x, y, such that the detectors form a two-dimensional structure (FIG. 8). The configuration is affected, for example, by masking during layer formation, such that the arrangement is effectively manufactured in a parallel manner in time. In addition, in further working examples, it is possible to connect or arrange x-ray detectors 300 alongside one another or successively to form a three-dimensional structure. By spatial offset of the x-ray detectors 300 relative to one another, an improvement in resolution is achieved.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method of manufacturing an electrooptical layer, a optoelectronic layer, or a electrooptical and optoelectronic layer, the method comprising:
forming the layer with perovskitic material having a composition ABX₃ by cold gas spraying of at least one starting material including the perovskitic material,
wherein X is formed by at least one halogen or a mixture of two or more halogens.

2. The method of claim 1, wherein A is formed by at least one cation or a mixture of two or more cations, B by at least one metallic or semi-metallic cation or a mixture of different cations, or A is formed by the at least one cation or the mixture of two or more cations and B is formed by the at least one metallic or semi-metallic cation or the mixture of different cations.

3. The method of claim 1, wherein the cold gas spraying is effected by aerosol-based cold deposition.

4. The method of claim 1, wherein the cold gas spraying is conducted in an operating atmosphere with at most 30 percent relative air humidity.

5. The method of claim 1, wherein the cold gas spraying is conducted in an operating atmosphere with at most 10 percent relative air humidity.

6. The method of claim 1, wherein the cold gas spraying is conducted in an inert atmosphere.

7. The method of claim 1, wherein the layer is formed with a layer thickness, at least in regions, of at least one micrometer.

8. The method of claim 1, wherein the layer is formed with a layer thickness, at least in regions, of at least ten micrometers.

9. The method of claim 1, wherein the layer is formed with a layer thickness, at least in regions, of at least 30 micrometers.

10. The method of claim 1, wherein the layer is formed with a layer thickness, at least in regions, of at least 100 micrometers.

11. The method of claim 1, wherein the layer is formed with a layer thickness, at least in regions, of less than 1 micrometer.

12. The method of claim 1, wherein the layer is formed with a layer thickness, at least in regions, of at most 200 nanometers.

13. The method of claim 1, wherein the layer is formed at a temperature of at most 200 degrees Celsius.

14. A method of producing an electrooptical device, a optoelectrical device, or an electrooptical and optoelectronic device comprising at least one electrooptical layer, at least one optoelectronic layer, or at least one electrooptical and at least one optoelectronic layer, the method comprising:
forming at least one layer with a perovskitic material by cold gas spraying of at least one starting material having the perovskitic material.

15. The method of claim 14, wherein the device is an energy transducer or a radiation detector,
wherein the at least one layer is an at least one sensor layer, or
wherein the device is an energy transducer or a radiation detector and the at least one layer is the at least one sensor layer.

16. The method of claim 15, wherein at least one further sensor layer is manufactured in a direction oblique to a direction of growth of the at least one sensor layer.

17. The method of claim 15, wherein at least one further sensor layer is manufactured in a direction transverse to, a direction of growth of the at least one sensor layer.

18. A device comprising:
an electrooptical layer, an optoelectronic layer, or an electrooptical and optoelectronic layer comprising a perovskitic material having a composition ABX₃ by cold gas spraying of at least one starting material having the perovskitic material,
wherein X is a halogen.

19. The device of claim 18, wherein the device is an energy transducer configured to convert electromagnetic energy to electrical energy or electrical energy to electromagnetic energy.

20. The device of claim 18, wherein the device is a solar cell, a light-emitting diode, or an x-ray detector.
